(19) United States
(12) Patent Application Publication
(10) Pub. No.: US 2013/0342236 A1
(43) Pub. Date: Dec. 26, 2013

(54) TEST INTERFACE BOARDS AND TEST SYSTEMS

(71) Applicant: SAMSUNG ELECTRONICS CO., LTD., Suwon-si (KR)

(72) Inventors: Ki-Jae Song, Paju-si (KR); Jong-Woon Yoo, Seoul (KR); Sang-Kyeong Han, Asan-si (KR); Gil-Beag Kim, Seoul (KR)

(73) Assignee: SAMSUNG ELECTRONICS CO., LTD., Suwon-si (KR)

(21) Appl. No.: 13/804,149

(22) Filed: Mar. 14, 2013

(30) Foreign Application Priority Data
Jun. 26, 2012 (KR) 10-2012-0068367

(51) Int. Cl. G01R 1/04

(52) U.S. Cl. CPC G01R 1/0408
USPC 324/756.07

(57) ABSTRACT

A test interface board comprises at least one switch matrix including a plurality of switching elements that connect a plurality of connection nodes to each other. The at least one switch matrix is configured to connect a plurality of channels of an automatic test equipment (ATE) to respective pin positions corresponding to a device under test (DUT) in response to switching control signals. The plurality of channels provide test operation signals for testing the DUT. A control logic is configured to generate the switching control signals based on pin configuration information of the DUT.

### CROSS-REFERENCE TO RELATED APPLICATION(S)

This application claims priority under 35 USC §119 to Korean Patent Application No. 2012-0068367, filed on Jun. 26, 2012, in the Korean Intellectual Property Office (KIPO), the content of which is incorporated herein in its entirety by reference.

### BACKGROUND

1. Technical Field

Exemplary embodiments relate to the field of device testing, and, more particularly, to a test interface board and test system for device testing.

2. Discussion of the Related Art

A test interface board receives a test signal from an automatic test equipment (ATE), and transmits the test signal to a device under test (DUT) for testing the device. For example, a test interface board in the form of a probe card receives a test signal from the ATE, and transmits the test signal through a trace on a printed circuit board (PCB) to the DUT. However, when the DUT is changed, configuration of the test interface board or probe card likewise needs to be changed.

### SUMMARY

Some example embodiments provide a test interface board capable of performing test without regard to attributes of pins of a device under test (DUT)

Some example embodiments relate to a test system including the test interface board. In some embodiments, the test interface board can be reconfigured so that the same test interface board is compatible for use with multiple devices under test having different pin configurations. In the manner, the cost for testing may be reduced.

In some embodiments, a test interface board comprises: at least one switch matrix including a plurality of switching elements that connect a plurality of connection nodes to each other, the at least one switch matrix configured to connect a plurality of channels of an automatic test equipment (ATE) to respective pin positions corresponding to a device under test (DUT) in response to switching control signals, the plurality of channels providing test operation signals for testing the DUT; and a control logic configured to generate the switching control signals based on pin configuration information of the DUT.

In some embodiments, each of the plurality of connection nodes is formed at intersection point of each of a plurality of first paths arranged to extend in a first direction and a plurality of second paths arranged to extend in a second direction transverse to the first direction. In some embodiments, the second direction can be transverse the first direction; in some embodiments, the second direction can be perpendicular to the first direction.

In some embodiments, the plurality of switching elements comprises: a plurality of row switching elements configured to selectively connect two adjacent connection nodes of the plurality of connection nodes arranged to extend in a first direction in response to the switching control signals; and a plurality of column switching elements configured to selectively connect two adjacent connection nodes of the plurality of connection nodes arranged to extend in a second direction that is transverse the first direction in response to the switching control signals.

In some embodiments, the at least one switch matrix comprises first and second switch matrices which are positioned on respective first and second layers, and the test interface board further comprises a plurality of interlayer switching elements configured to selectively connect first connection nodes in the first switch matrix on the first layer to corresponding second connection nodes in the second switch matrix on the second layer.

In some embodiments, the plurality of interlayer switching elements are configured to provide non-overlapping test signal paths when connections between the plurality of channels and the corresponding pin positions overlap in a same switch matrix.

In some embodiments, the plurality of interlayer switching elements comprise a plurality of transistors that are turned-on/off in response to the switching control signals.

In some embodiments, the plurality of interlayer switching elements comprise a plurality of two-terminal switches that are connected/disconnected in response to the switching control signals.

In some embodiments, the switching elements comprise a plurality of transistors that are turned-on/off in response to the switching control signals.

In some embodiments, the switching elements comprise a plurality of two-terminal switches that are connected/disconnected in response to the switching control signals.

In some embodiments, the at least one switch matrix comprises: a first switching unit including first switching elements that switch a control signal and a test pattern signal of the test operation signals in response to first switching control signals; and a second switching unit including second switching elements that switch one of output of the first switching unit, a power supply voltage and a ground voltage to provide the switched one to the pin positions in response to second switching control signals.

In some embodiments, the control logic comprises: a register that stores the pin configuration information; and a switching signal generator configured to generate the switching control signals based on the pin configuration information stored in the register.

In some embodiments, the register comprises a mode set register that stores the pin configuration information.

In some embodiments, when the DUT is changed, the at least one switch matrix provides reconfigurable test signal paths connecting the channels to the corresponding pin positions of the changed DUT in response to the switching control signals.

In some embodiments, a test system comprises: an automatic test equipment (ATE) configured to generate test operation signals; a device under test (DUT) that receives the test operation signals to output test result signals in response to test pattern signals of the test operation signals; and a test interface board configured to transfer the test operation signals to the DUT, wherein the test interface board comprises: at least one switch matrix including a plurality of switching elements that connect a plurality of connection nodes to each other, the at least one switch matrix configured to connect a plurality of channels of the ATE to respective pin positions corresponding to the DUT in response to switching control signals, the plurality of channels providing test operation signals for testing the DUT; and a control logic configured to generate the switching control signals based on pin configuration information of the DUT.

In some embodiments, the plurality of switching elements comprises: a plurality of row switching elements configured to selectively connect two adjacent connection nodes of the plurality of connection nodes arranged to extend in a first direction in response to the switching control signals; and a plurality of column switching elements configured to selectively connect two adjacent connection nodes of the plurality of connection nodes arranged to extend in a second direction that is transverse the first direction in response to the switching control signals.

In some embodiments, the at least one switch matrix comprises first and second switch matrices which are positioned on respective first and second layers, and the test interface board further comprises a plurality of interlayer switching elements configured to selectively connect first connection nodes in the first switch matrix on the first layer to corresponding second connection nodes in the second switch matrix on the second layer, and the plurality of interlayer switching elements are configured to provide non-overlapping test signal paths when connections between the plurality of channels and the corresponding pin positions overlap in a same switch matrix.

In some embodiments, a test interface board, comprises: a plurality of nodes arranged in a matrix having a first direction of extension and a second direction of extension, the first and second directions being transverse each other; a plurality of first switching elements configured to selectively connect adjacent nodes arranged in the first direction in response to switching control signals; a plurality of second switching elements configured to selectively connect adjacent nodes arranged in the second direction in response to the switching control signals; a plurality of first positions corresponding to channels of an automated test equipment (ATE) and a plurality of second positions corresponding to pin positions of a device under test (DUT), wherein, in response to the switching control signals, the test interface board is programmed to provide multiple test signal paths, a signal path being between a selected one of the plurality of first positions and a selected one of the plurality of second positions, and the signal path further including a selected plurality of the nodes selectively connected by the first and second switching elements.

In some embodiments, the nodes and first and second switching elements are arranged on first and second layers, each of the first and second layers comprising a plurality of nodes, a plurality of first switching elements and a plurality of second switching elements, and further comprising a plurality of third switching elements configured to selectively connect adjacent nodes of the first and second layers.

In some embodiments, the signal path further includes selected nodes of the first and second layers selectively connected by the third switching elements.

In some embodiments, two signal paths that otherwise would intersect on one of the first and second layers, are configured to overlap through the third switching elements and nodes of the other of the first and second layers.

Accordingly, when the DUT is changed and attributes of the pins of the DUT are changed, the test interface board may provide reconfigurable test signal paths to the DUT. Therefore, overall costs for testing may be reduced.

### BRIEF DESCRIPTION OF THE DRAWINGS

Illustrative, non-limiting, exemplary embodiments will be more clearly understood from the following detailed description taken in conjunction with the accompanying drawings.

FIG. 1 is a block diagram illustrating a test system including a test interface board according to example embodiments.

FIG. 2 is a block diagram illustrating an example of the automatic test equipment (ATE) in FIG. 1 according to example embodiments.

FIG. 3 illustrates an example of the driver channels of the embodiment of FIGS. 1 and 2 according to example embodiments.

FIG. 4 illustrates an example of the I/O channels of the embodiment of FIGS. 1 and 2 according to example embodiments.

FIG. 5 illustrates an example of the at least one switch matrix layer of FIG. 1 according to example embodiments.

FIG. 6 illustrates an example of the switch matrix layer of FIG. 5 according to example embodiments.

FIGS. 7 and 8 respectively illustrate examples of the switching elements of the embodiment of FIG. 6 according to example embodiments.

FIG. 9 illustrates an example of connection relationship of the test interface board of the embodiment of FIG. 1 according to example embodiments.

FIG. 10 illustrates another example of connection relationship of the test interface board of the embodiment of FIG. 1 according to example embodiments.

FIG. 11 illustrates an example of the at least one switch matrix layer of the embodiment of FIG. 9 or 10 according to example embodiments.

FIG. 12 illustrates a position where the test signal paths are overlapped according to example embodiments.

FIGS. 13 and 14 respectively illustrate examples of the interlayer switching elements of the embodiment of FIG. 12 according to example embodiments.

FIG. 15 illustrates another example of the test interface board of FIG. 1 according to example embodiments.

FIG. 16 illustrates connection relationship of one connection node and switching elements in FIG. 15 according to example embodiments.

FIG. 17 is a block diagram illustrating an example of the control logic of FIG. 1 according to example embodiments.

FIG. 18 is a block diagram illustrating a test system according to example embodiments.

### DETAILED DESCRIPTION OF EMBODIMENTS

Various exemplary embodiments will be described more fully hereinafter with reference to the accompanying drawings, in which some exemplary embodiments are shown. The present inventive concepts may, however, be embodied in many different forms and should not be construed as limited to the exemplary embodiments set forth herein. Rather, these exemplary embodiments are provided so that this disclosure will be thorough and complete, and will fully convey the scope of the present inventive concepts to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concepts. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular exemplary embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

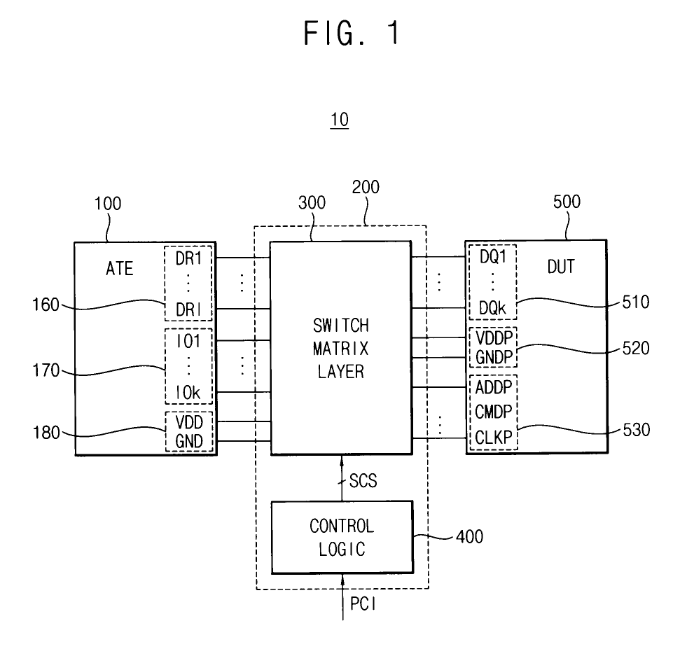

FIG. 1 is a block diagram illustrating a test system including a test interface board according to example embodiments.

Referring to FIG. 1, a test system 10 includes an automatic test equipment (ATE) 100, a device under test (DUT) 500 and a test interface board 200.

The ATE 100 generates test operation signals for testing the DUT 500. The test interface board 200 receives generated test operation signals from the ATE 100 and transfers returned test result operation signals to the ATE 100. The ATE 100 receives the returned test result operation signals and operates in response to the returned test result operation signals, either by simply capturing and storing the returned test result operation signals, or also by generating additional test operation signals for the DUT 500 in response to the returned test result operation signals from the DUT 500.

For example, when a manufacturing process of a semiconductor device is completed, electrical parameters of the semiconductor device may be measured by the ATE 100 to perform a pass/fail test of the manufactured semiconductor device. The ATE 100 may generate the test operation signals for performing a pass/fail test of the manufactured semiconductor device such as DUT 500. The DUT 500 is mounted to the test interface board 200. The test interface board 200 receives the test operation signals from the ATE 100 to apply the test operation signals to a plurality of pins of the DUT 500. The DUT 500 may perform a predetermined operation in response to the generated test operation signals received through the pins. In some embodiments, the DUT 500 may generate test result signals as a result of the predetermined operation. The test interface board 200 receives the test result signals from the DUT 500 and transfers the test result signal to the ATE 100. The ATE 110 may determine whether the DUT 500 passes or fails a given test based on the test result signals.

When the DUT 500 is changed so that a different device is being tested by the ATE 100, attributes of pins of the DUT 500, which receive the test operation signals from the ATE 100 and which generate test result signals to be returned to the ATE 100, may likewise be changed. That is, in one example test situation, the DUT 500 may be changed from a first memory device having a first pin configuration to a second memory device having a second pin configuration. In accordance with embodiments of the present inventive concepts, the test interface board 200 may provide reconfigurable test signal paths connecting the channels of the ATE 100 to the corresponding pins of a different DUT 500, when the DUT 500 is changed.

In some embodiments, the ATE 100 may include driver channels 160 (DR1˜DR1) for transferring the generated test operation signals, input/output (I/O) channels 170 (IO1˜IOk) and power channels 180 (VDD, GND, etc.). In some embodiments, the driver channels 160 provide command signals, address signals and a clock signal. In some embodiments, the I/O channels 170 provide test pattern signals. In some embodiments, the power channels 180 provide a power supply voltage VDD and a ground voltage GND, and other suitable voltage signals.

The DUT 500 includes data I/O pins 510 (DQ1˜DQk), power pins 520 (VDDP, GNDP, etc) and control pins 530 (ADDP, CMDP, CLKP, etc.). In various embodiments, the data I/O pins 510 and control pins 530 can be unidirectional input or output pins, or bidirectional pins.

In accordance with embodiments of the present inventive concepts, the test interface board 200 may include at least one switch matrix layer 300 and a control logic 400.

The control logic 400 generates a plurality of switching control signals SCS based on pin configuration information PCI of the DUT 500. The at least one switch matrix layer 300 includes a plurality of switches having states that can be programmed in response to the switching control signals SCS and provides reconfigurable test signal paths connecting the various channels 160, 170 and 180 of the ATE 100 to the pins 510, 520 and 530 having corresponding attributes of the DUT 500. For example, the switch matrix layer 300 may connect the driver channels 160 of the ATE 100 to the control pins 530 of the DUT 500, connect the I/O channels 170 of the ATE 100 to the data I/O pins 510 of the DUT 500 and connect the power channels 180 of the ATE 100 to the power pins 520 of the DUT 500.

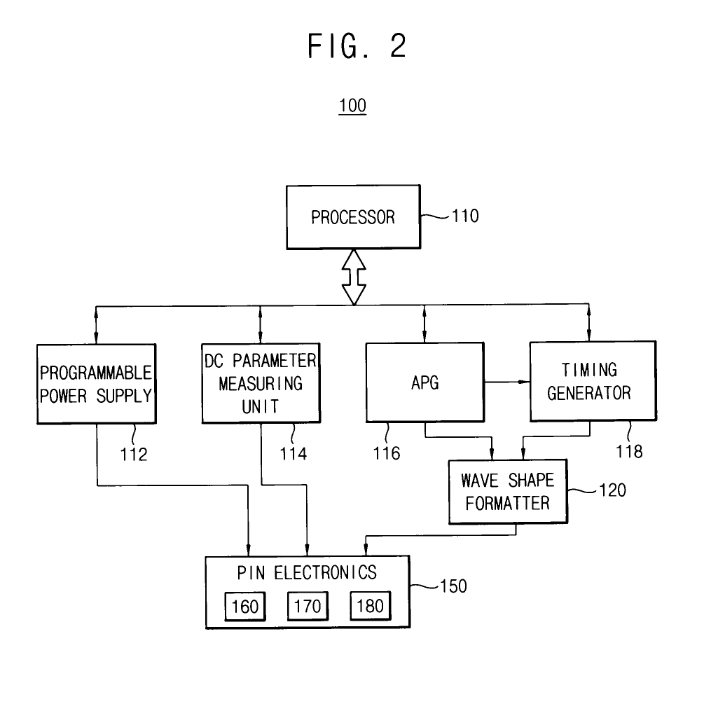

FIG. 2 is a block diagram illustrating an example of the automatic test equipment (ATE) in FIG. 1 according to example embodiments.

Referring to FIG. 2, the ATE 100 includes a processor 110 for controlling hardware components of the ATE 100. In some example embodiments, the hardware components include a programmable power supply 112, a DC parameter measurement unit 114, an algorithmic pattern generator 116, a timing generator 118, a wave shape formatter 120, a pin electronics 150, and the like. The pin electronics 150 includes the driver channels 160, the I/O channels 170 and the power channels 180. In the ATE 100, a test program running on the processor 110 communicates signals and electrically tests functions of the DUT 500 connected via the pin electronics 150 by using the test interface board 200.

The test program for testing the DUT 500 typically includes a DC test, an AC test, and a function test. The function test commonly operates to check the functionality of a semiconductor memory device, for example a DRAM, under its actual operational condition. That is, in some test program configurations an input pattern from the algorithmic pattern generator 116 of the ATE is written to the DUT 500, for example, the DRAM (write operation), and a returned output pattern from the DRAM is read out (read operation) and compared at the ATE 100 to an expected return pattern by a comparator (compare operation).

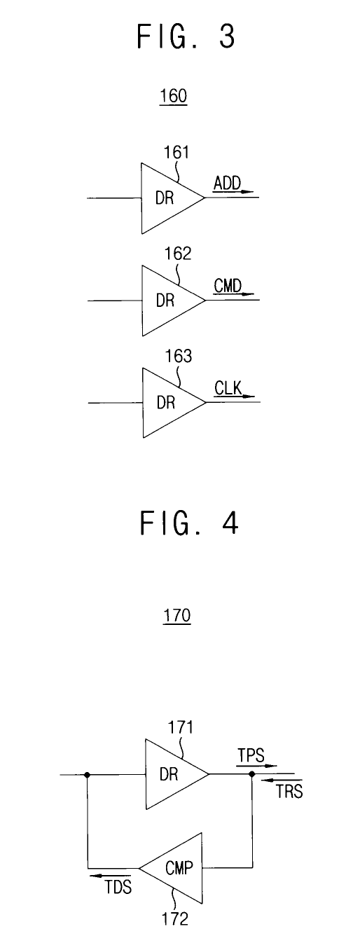

FIG. 3 illustrates an example of the driver channels of the embodiments of FIGS. 1 and 2 according to example embodiments.

Referring to FIG. 3, the driver channels 160 may include a plurality of drivers 161, 162 and 163. The driver 161 provides the address signal ADD, the driver 162 provides the command signal CMD and the driver 163 provides the clock signal CLK. In this example embodiment, the driver channels 160 are uni-directional channels for providing the address signal ADD, the command signal CMD and the clock signal CLK to the corresponding pins of the DUT 500. Other control signals for controlling the functionality of the DUT 500 can likewise be generated by the ATE 100 and output to the DUT 500 via the driver channels 160.

FIG. 4 illustrates an example of the I/O channels of the embodiments of FIGS. 1 and 2 according to example embodiments.

Referring to FIG. 4, the I/O channels 170 may include a driver 171 and a comparator 172. The driver 171 provides the data I/O pins 510 of the DUT 500 through the test interface board 200 with a test pattern signal TPS provided from the algorithmic pattern generator 116 and the wave shape formatter 120. The comparator 172 receives the test result signal TRS from the DUT 500, compares the test result signal TRS with the test pattern signal TPS and outputs test determining signal TDS having a logic level according to a result of the comparison. For example, the comparator 172 may output the test determining signal TDS having a first logic level (i.e., logic high level) when the test result signal TRS matches with the expected test pattern signal TPS. For example, the comparator 172 may output the test determining signal TDS having a second logic level (i.e., logic low level) when the test result signal TRS does not match with the expected test pattern signal TPS. Therefore, the ATE 100 may determine whether the DUT 500 passes or fails based on the test determining signal TDS.

In some example embodiments, according to alternative embodiments, the I/O channels 170 may be bi-directional channels for providing the test pattern signal TPS to the DUT 500 and receiving the returned test result signal TRS. In this example, the returned test result signal TRS is buffered by a return buffer or driver 172 and transmitted to the ATE 100 for signal comparison or analysis.

In some example embodiments, the comparator 172 may be included in the test interface board 200. When the test interface board 200 is included in the test interface board 200, the comparator 172 may be implemented with an additional driver that outputs the test determining signal TDS to the ATE 100.

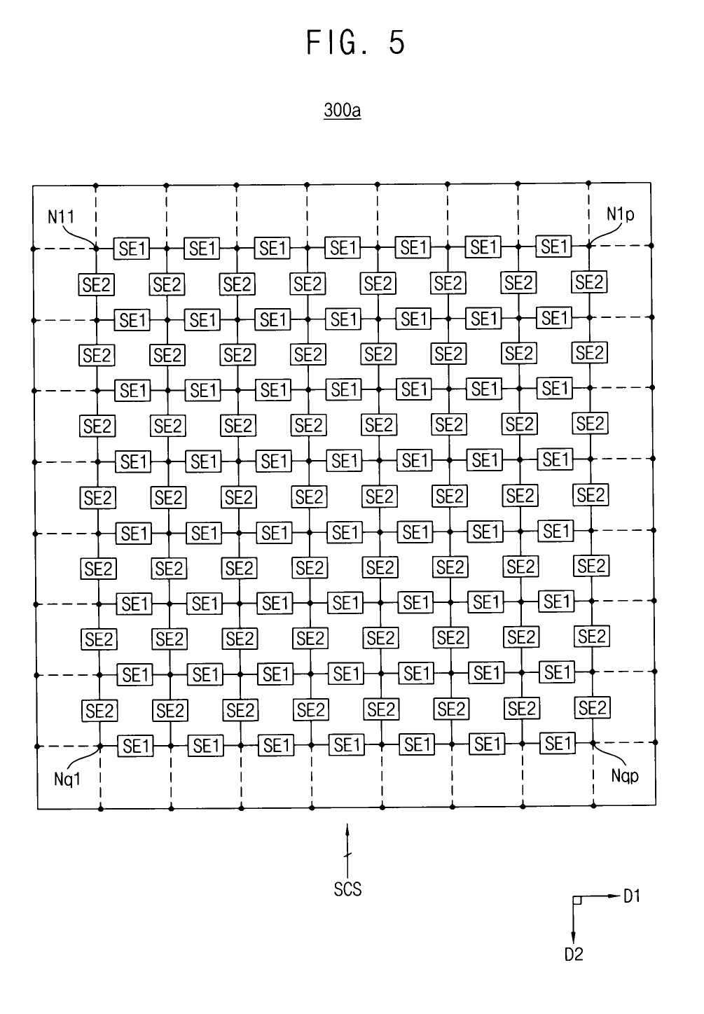

FIG. 5 illustrates an example of the at least one switch matrix layer of the embodiment of FIG. 1 according to example embodiments.

Referring to FIG. 5, at least one switch matrix layer 300a includes a plurality of switching elements SE1 and SE2 that selectively connect a plurality of connection nodes N11˜N1p, . . . , Nq1˜Nqp in response to the switching control signals SCS to provide reconfigurable test signal paths. The plurality of switching elements SE1 and SE2 include a plurality of row switching elements SE1 and a plurality of column switching elements SE2. The row switching elements SE1 selectively connect two adjacent connection nodes N11˜N1p, . . . , Nq1˜Nqp in a first direction D1, for example a row direction, of the matrix. The column switching elements SE2 selectively connect two adjacent connection nodes N11˜N1p, . . . , Nq1˜Nqp in a second direction D2, for example, a column direction, of the matrix. Each of the connection nodes N11˜N1p, . . . , Nq1˜Nqp is formed at an intersection point of each of a plurality of first paths in the first direction D1 and each of a plurality of second paths in the second direction D2. The plurality of switching elements SE1 and SE2 are switched to connect selectively connect two adjacent connection nodes N11˜N1p, . . . , Nq1˜Nqp in response to the switching control signal SCS generated based on the pin configuration information PCI associated with the corresponding DUT 500 and provide the reconfigurable test signal paths between the channels 160, 170 and 180 of the ATE 100 and the pins 510, 520 and 530 of the DUT 500. Therefore, the test interface board 200 may provide reconfigurable test signal paths connecting the channels of the ATE 100 to the corresponding pins of the changed DUT 500 when the DUT 500 is changed. Although not illustrated, the least one switch matrix layer 300a may include a plurality of switching elements for connecting the connection nodes in a diagonal direction.

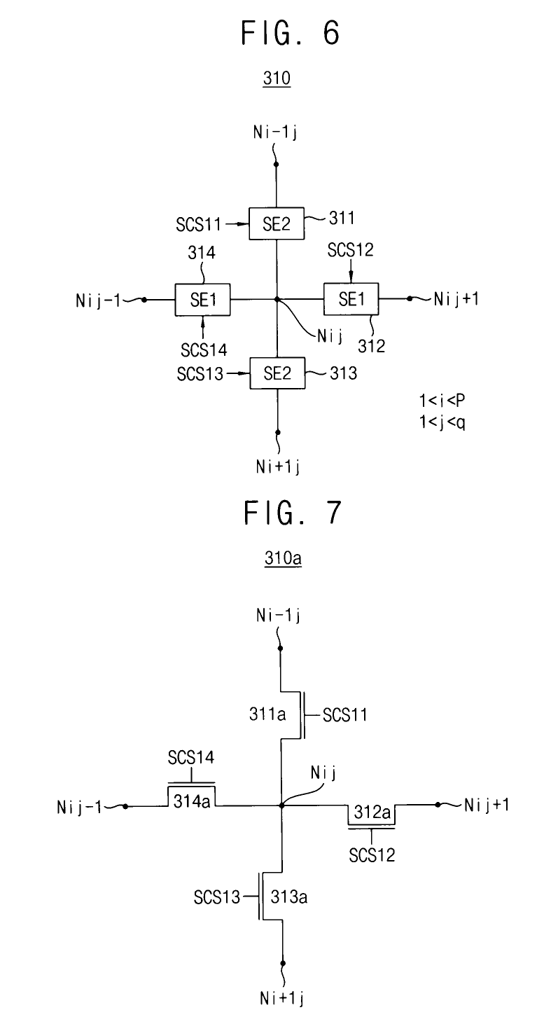

FIG. 6 illustrates an example of the switch matrix layer of FIG. 5 according to example embodiments.

In FIG. 6, there is illustrated a connection relationship between a connection node Nij and switching elements SE1 and SE2. Referring to FIG. 6, the connection node Nij is connected to each of adjacent, or neighboring, connection nodes through each of switching elements 311, 312, 313 and 314. For example, the switching element 311 selectively connects the node Nij with the adjacent node Ni−1j in response to a switching control signal SCS11. The switching element 312 selectively connects the node Nij with the adjacent node Nij+1 in response to a switching control signal SCS12. The switching element 313 selectively connects the node Nij with the adjacent node Ni+1j in response to a switching control signal SCS13. The switching element 314 selectively connects the node Nij with the adjacent node Nij−1 in response to a switching control signal SCS14.

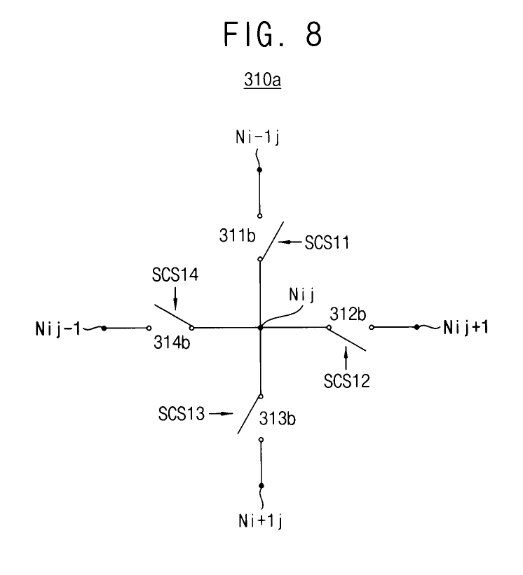

FIGS. 7 and 8 respectively illustrate examples of the switching elements of the embodiment of FIG. 6 according to example embodiments.

Referring to FIG. 7, the switching elements 311, 312, 313 and 314 may comprise n-channel metal oxide semiconductor (NMOS) transistors 311a, 312a, 313a and 314a each transistor having a gate receiving a corresponding switching control signals SCS 11, SCS 12, SCS 13 and SCS 14. The NMOS transistor 311a selectively connects the node Nij with the adjacent node Ni−1j in response to the switching control signal SCS11. The NMOS transistor 312a selectively connects the node Nij with the adjacent node Nij+1 in response to the switching control signal SCS12. The NMOS transistor 313a selectively connects the node Nij with the adjacent node Ni+1j in response to the switching control signal SCS13. The NMOS transistor 314a selectively connects the node Nij with the adjacent node Nij−1 in response to the switching control signal SCS14.

Referring to FIG. 8, the switching elements 311, 312, 313 and 314 may comprise two-terminal switches 311b, 312b, 313b and 314b each receiving a corresponding switching control signal SCS11, SCS12, SCS13 and SCS14. The two-terminal switch 311b selectively connects the node Nij with the adjacent node Ni−1j in response to the switching control signal SCS11. The two-terminal switch 312b selectively connects the node Nij with the adjacent node Nij+1 in response to the switching control signal SCS12. The two-terminal switch 313b selectively connects the node Nij with the adjacent node Ni+1j in response to the switching control signal SCS13. The two-terminal switch 314b selectively connects the node Nij with the adjacent node Nij−1 in response to the switching control signal SCS14.

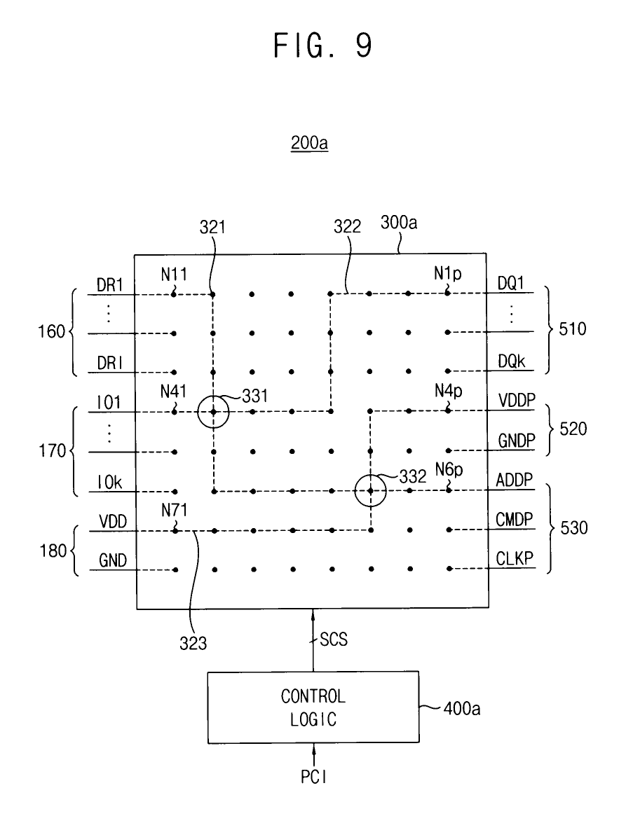

FIG. 9 illustrates an example of connection relationship of the test interface board in FIG. 1 according to example embodiments. In FIG. 9, the switching elements SE1 and SE2 in FIG. 5 are not illustrated for sake of convenience.

Referring to FIG. 9, a driver DR1 of the driver channels 160 of the ATE 100 transfers the address signal ADD to the address pin ADDP of the DUT 500 through a test signal path 321 from the connection node N11 to the connection node N6p. The switching elements SE1 and SE2 in the test signal path 321 connect adjacent connection nodes to each other in response to the switching control signals SCS provided. An I/O channel 101 of the I/O channels 170 of the ATE 100 transfers the test pattern signal TPS to the data I/O pin DQ1 of the DUT 500 and may receive the test result signal TRS from data I/O pin DQ1 through a test signal path 322 configured between the connection node N41 and the connection node Nlp. The switching elements SE1 and SE2 positioned in the test signal path 322 connect adjacent connection nodes to each other in response to the switching control signals SCS. The power channel 180 of the ATE 100 transfers the power supply voltage VDD to the power pin VDDP of the DUT 500 through a test signal path 323 from the connection node N71 to the connection node N4p. The switching elements SE1 and SE2 in the test signal path 323 connect adjacent connection nodes to each other in response to the switching control signals SCS.

In FIG. 9, the test signal paths 321 and 322 are overlapped, or intersect, with each other at the region indicated by reference numeral 331 and the test signal paths 321 and 323 are overlapped, or intersect, with each other at the region indicated by reference numeral 332.

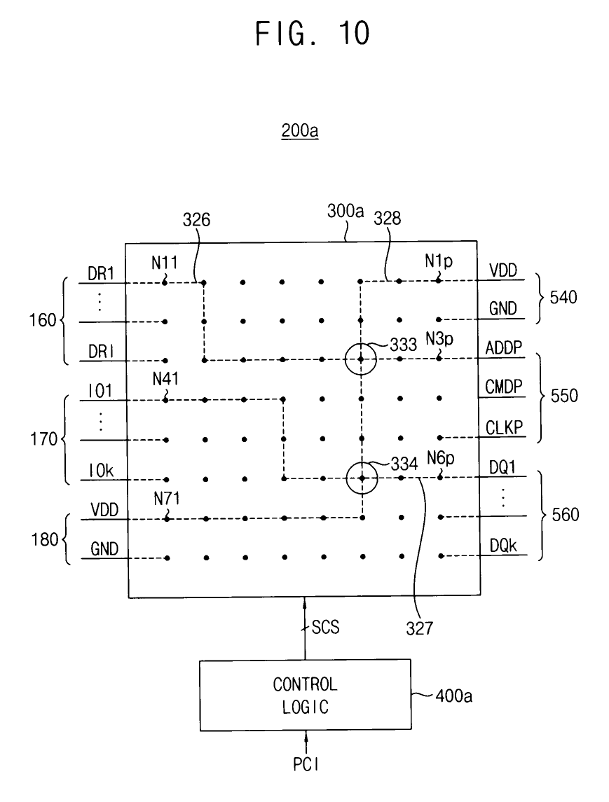

FIG. 10 illustrates another example of connection relationship of the test interface board in FIG. 1 according to example embodiments. In FIG. 10, the switching elements SE1 and SE2 in FIG. 5 are not illustrated for sake of convenience. Also, the DUT in the example embodiment of FIG. 10 has been changed relative to the DUT of the example embodiment of FIG. 9. Therefore, attributes of the pins of the DUT are also changed in FIG. 10, relative to FIG. 9. That is, locations of the power pins 540, the control pins 550 and the data I/O pins 560 in the example of FIG. 10 are different from the locations of the power pins 530, the control pins 520 and the data I/O pins 510 in the example of FIG. 9.

Referring to FIG. 10, the driver DR1 in the driver channels 160 of the ATE 100 transfers the address signal ADD to the address pin ADDP of the DUT 500 through a test signal path 326 configured between the connection node N11 and the connection node N3p. The switching elements SE1 and SE2 in the test signal path 326 connect adjacent connection nodes to each other in response to the switching control signals SCS. An I/O channel 101 in the I/O channels 170 of the ATE 100 transfers the test pattern signal TPS to the data I/O pin DQ1 of the DUT 500 and may receive the test result signal TRS from data I/O pin DQ1 through a test signal path 327 configured between the connection node N41 to the connection node N6p. The switching elements SE1 and SE2 in the test signal path 327 connect adjacent connection nodes to each other in response to the switching control signals SCS. The power channel 180 of the ATE 100 transfers the power supply voltage VDD to the power pin VDDP of the DUT 500 through a test signal path 328 configured between the connection node N71 to the connection node Nlp. The switching elements SE1 and SE2 in the test signal path 328 connect adjacent connection node to each other in response to the switching control signals SCS.

In FIG. 10, the test signal paths 326 and 328 are overlapped, or intersect, with each other at a region indicated by reference numeral 333 and the test signal paths 327 and 328 are overlapped, or intersect, with each other at a region indicated by reference numeral 334.

In a conventional test system including a conventional test interface board, a newly configured test interface board must be deployed each time the attributes of the pins of the DUT 500 are changed. However, referring to the test interface board configured in accordance with the present inventive concepts, with reference to FIGS. 9 and 10, even in a case where the attributes of the pins of the DUT 500 are changed, the test interface board 200 provides reconfigurable test signal paths that connect channels 160, 170 and 180 of the ATE to corresponding pins of the DUT 500. This is possible because the test interface board 200 includes the switching elements SE1 and SE2 which are selectively activated and deactivated in response to the switching control signals SCS.

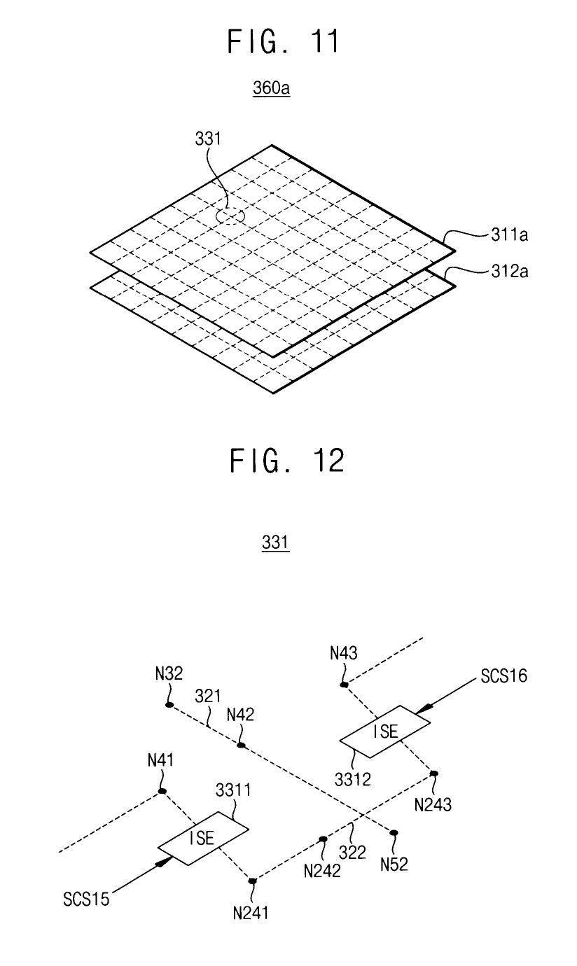

FIG. 11 illustrates an example of the at least one switch matrix layer of the embodiment of FIG. 9 or 10 according to example embodiments. Referring to FIG. 11, the at least one switch matrix layer 360a includes first and second layers 311a and 312a which are multi-layered. Each of the first and second layers 311a and 312a may employ the switch matrix layer 300a of FIG. 5. The first layer 311a includes a plurality of switching elements that selectively connect a plurality of connection nodes in response to the switching control signals SCS to provide reconfigurable test signal paths. The second layer 312a likewise includes a plurality of switching elements that selectively connect a plurality of connection nodes in response to the switching control signals SCS to provide reconfigurable test signal paths. First connection nodes in the first layer 311a and the second connection nodes in the second layer 312a may be connected to each other respectively through interlayer switching elements in FIG. 12. In the example embodiment of FIG. 11, the reference numeral 331 indicates that the test signal paths 321 and 322 in FIG. 9 are overlapped.

FIG. 12 illustrates a position where the test signal paths are overlapped according to example embodiments.

Referring to FIG. 12, overlapping of the test signal paths in a same layer may be avoided by employing interlayer switching elements 3311 and 3312. The interlayer switching element 3311 may be configured to connect the connection node N41 in the first layer 311a and the connection node N241 in the second layer 312a to each other in response to a switching control signal SCS15. Similarly, the interlayer switching element 3312 may connect the connection node N43 in the first layer 311a and the connection node N243 in the second layer 312a to each other in response to a switching control signal SCS 16. That is, at the position 331 where the test signal paths are overlapped, the test signal path 321 may use nodes and switching elements positioned on the first layer 311a and the test signal path 322 may use nodes and switching elements positioned on the second layer 312a. The interlayer switching elements 3311 and 3312 may include transistors having a gate receiving the switching control signal as in FIG. 7 or may include two-terminal switches as in FIG. 8, or may have other suitable switching units.

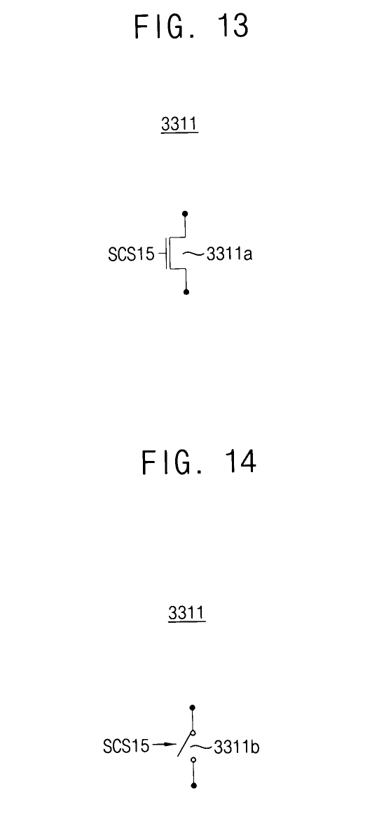

FIGS. 13 and 14 respectively illustrate examples of the interlayer switching elements of the embodiment of FIG. 12 according to example embodiments.

Referring to FIG. 13, in this embodiment, the interlayer switching element 3311 may include a NMOS transistor 3311a having a gate receiving the switching control signal SCS15 and which selectively connects the connection node N41 in the first layer 311a with the connection node N241 in the second layer 312a.

Referring to FIG. 14, in this embodiment, the interlayer switching element 3311 may include two-terminal switch 3311b which is connected/disconnected in response to the switching control signal SCS15 and selectively connects the connection node N41 in the first layer 311a with the connection node N241 in the second layer 312a. Although these two types of switching units are shown herein in connection with FIGS. 7, 8, 13, and 14, other forms of switches may be suitable and applicable to the principles of the present inventive concepts.

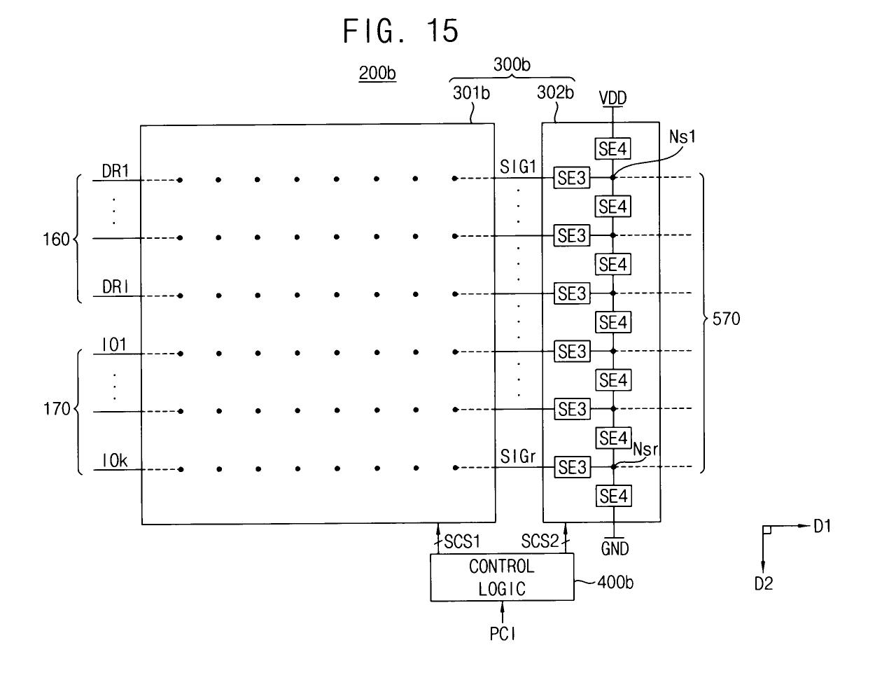

FIG. 15 illustrates another example of the test interface board of FIG. 1 according to example embodiments.

Referring to FIG. 15, a test interface board 200b includes a switch matrix layer 300b and a control logic 400b.

The switch matrix layer 300b includes first and second switching units 301b and 302b. The switching unit 301b is configured substantially similarly to the switch matrix layer 300a of FIG. 5 and is connected to the driver channel 160 and the I/O channel 170 to provide reconfigurable signal paths for the control signals and the test pattern signals. In addition, the first switching unit 301b provides the second switching unit 302b with the control signals and the test pattern signals as signals SIG1˜SIGr. The first switching unit 301b may include a plurality of layers as illustrated in FIG. 11.

The second switching unit 302b includes a plurality of switching elements SE3 and SE4. The switching elements SE3 selectively connect each of the signals SIG1˜SIGr to each of connection nodes NS1˜Nsr in a first direction D1. The switching elements SE4 selectively connect each of connection nodes NS1˜Nsr to the power supply voltage VDD or the ground voltage GND. Therefore, when attributes of the pins of the DUT 500 are changed from the signals SIG1˜SIGr including the control signals and the test pattern signals to the power supply voltage VDD or the ground voltage GND or are changed from the power supply voltage VDD or the ground voltage GND to the signals SIG1˜SIGr including the control signals and the test pattern signals, the test interface board 300b may connect the driver channel 160 and the I/O channel 170 to the corresponding pins of the DUT 500 through the switching operation of the first and second switching units 301b and 302b without altering configuration of the test interface board 200b. The control logic 400b provides first switching control signals SCS1 to the first switching unit 301b and provides second switching control signals SCS2 to the second switching unit 302b based on the pin configuration information PCI.

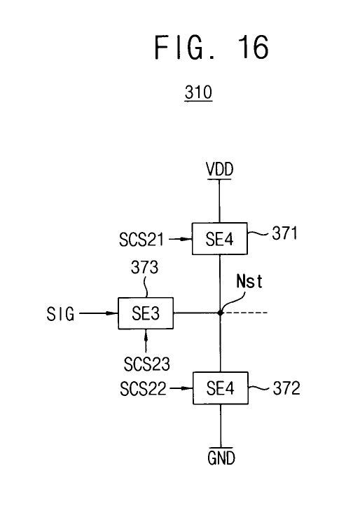

FIG. 16 illustrates connection relationship of one connection node and switching elements in FIG. 15 according to example embodiments.

Referring to FIG. 16, switching elements 371, 372 and 373 are connected to a node Nst. The switching element 371 selectively connects the power supply voltage VDD to the connection node Nst in response to a switching control signal SCS21, the switching element 372 selectively connects the ground voltage GND to the connection node Nst in response to a switching control signal SCS22, and the switching element 373 selectively connects the signal SIG to the connection node Nst in response to a switching control signal SCS22. Here, t is a natural number greater than one and less than r.

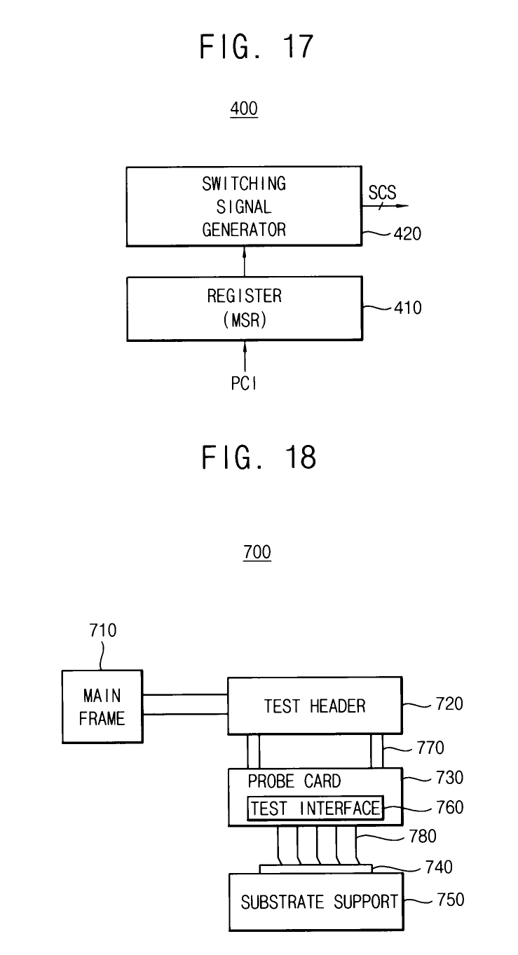

FIG. 17 is a block diagram illustrating an example of the control logic of FIG. 1 according to example embodiments.

Referring to FIG. 17, in some embodiments of the present inventive concepts, the control logic 400 may include a register 410 and a switching signal generator 420.

The register 410 can be configured to store the pin configuration information PCI indicating, for example, attributes of the pins of the DUT 500. In some embodiments, new pin configuration information PCI may be provided to the register 410 whenever a new DUT 500 is to be tested. The switching signal generator 420 generates the switching control signal SCS based on the pin configuration information PCI and provides the at least one switch matrix with the switching control signal SCS for managing and configuring the reconfigurable test signal paths connecting the channels 160, 170 and 180 of the ATE 100 to the corresponding pins of the DUT 500. The switching elements SE1 and SE2 may selectively connect the connection nodes to provide the reconfigurable test signal paths in response to the switching control signal SCS.

In some embodiments, the register 410 may comprise a mode set register (MSR) and may provide the switching signal generator 420 with information for generating the switching control signal SCS according to the pin configuration information PCI.

FIG. 18 is a block diagram illustrating a test system according to example embodiments.

Referring to FIG. 18, a test system 700 includes a test main frame 710, a test header 720, a probe card 730, a wafer 740, and a substrate support 750. The wafer 740 may include a plurality of semiconductor devices that are to be tested.

The test main frame 710 may generate a test signal, and may receive test result signals generated by the semiconductor devices formed in the wafer 740. In some embodiments, the test header 720 may move up and down such that the probe card 730 may be easily attached to the test header 720 and the wafer 740 may be easily mounted on the substrate support 750. In other embodiments, the substrate support 750 may move up and down while the test header 720 is fixed. In still other embodiments, both of the test header 720 and the substrate support 750 may together move up and down. The test main frame 710, the test header 720 and the substrate support 750 may constitute an ATE.

The probe card 730 may include a test interface board 760, a connector 770 and probe needles 780. The connector 770 may connect the test header 720 to the test interface board 760, and the probe needles 780 may connect the test interface board 760 to pads of the semiconductor devices. The test interface board 760 transmits the test operating signals from the connector 770 to the probe needle 780 through reconfigurable test signal paths. In addition, the test interface board 760 transmits the test result signal from the probe needle 780 to the connector 770 through the reconfigurable test signal paths. In this manner, the overall test cost of the test system 700 may be reduced because the test interface board 760 need not be changed even in case where the attributes of the pads of the wafer 740 are changed. This is because, in accordance with the present inventive concepts, the test interface board 760 can be reconfigured so that the various channels of the ATE can be connected to the various probe needles of the probe card in different ways. Therefore, different types of devices present on the wafer 740 can be tested without the need for changing the test interface board 760.

As mentioned above, according to example embodiments, when the DUT is changed and attributes of the pins of the DUT are changed, the test interface board may provide reconfigurable test signal paths to the DUT. Therefore, the resulting costs of performing device testing may be reduced. Also, the inventive concepts may be applied to various test systems.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A test interface board comprising:
at least one switch matrix including a plurality of switching elements that connect a plurality of connection nodes to each other, the at least one switch matrix configured to connect a plurality of channels of an automatic test equipment (ATE) to respective pin positions corresponding to a device under test (DUT) in response to switching control signals, the plurality of channels providing test operation signals for testing the DUT; and
a control logic configured to generate the switching control signals based on pin configuration information of the DUT.

2. The test interface board of claim 1, wherein each of the plurality of connection nodes is formed at intersection point of each of a plurality of first paths arranged to extend in a first direction and a plurality of second paths arranged to extend in a second direction transverse to the first direction.

3. The test interface board of claim 1, wherein the plurality of switching elements comprises:
a plurality of row switching elements configured to selectively connect two adjacent connection nodes of the plurality of connection nodes arranged to extend in a first direction in response to the switching control signals; and
a plurality of column switching elements configured to selectively connect two adjacent connection nodes of the plurality of connection nodes arranged to extend in a second direction that is transverse the first direction in response to the switching control signals.

4. The test interface board of claim 1, wherein the at least one switch matrix comprises first and second switch matrices which are positioned on respective first and second layers, and
wherein the test interface board further comprises a plurality of interlayer switching elements configured to selectively connect first connection nodes in the first switch matrix on the first layer to corresponding second connection nodes in the second switch matrix on the second layer.

5. The test interface board of claim 4, wherein the plurality of interlayer switching elements are configured to provide non-overlapping test signal paths when connections between the plurality of channels and the corresponding pin positions overlap in a same switch matrix.

6. The test interface board of claim 4, wherein the plurality of interlayer switching elements comprise a plurality of transistors that are turned-on/off in response to the switching control signals.

7. The test interface board of claim 4, wherein the plurality of interlayer switching elements comprise a plurality of two-terminal switches that are connected/disconnected in response to the switching control signals.

8. The test interface board of claim 1, wherein the switching elements comprise a plurality of transistors that are turned-on/off in response to the switching control signals.

9. The test interface board of claim 1, wherein the switching elements comprise a plurality of two-terminal switches that are connected/disconnected in response to the switching control signals.

10. The test interface board of claim 1, wherein the at least one switch matrix comprises:
a first switching unit including first switching elements that switch a control signal and a test pattern signal of the test operation signals in response to first switching control signals; and
a second switching unit including second switching elements that switch one of output of the first switching unit, a power supply voltage and a ground voltage to provide the switched one to the pin positions in response to second switching control signals.

11. The test interface board of claim 1, wherein the control logic comprises:
a register that stores the pin configuration information; and
a switching signal generator configured to generate the switching control signals based on the pin configuration information stored in the register.

12. The test interface board of claim 11, wherein the register comprises a mode set register that stores the pin configuration information.

13. The test interface board of claim 1, wherein when the DUT is changed, the at least one switch matrix provides reconfigurable test signal paths connecting the channels to the corresponding pin positions of the changed DUT in response to the switching control signals.

14. A test system comprising:
an automatic test equipment (ATE) configured to generate test operation signals;
a device under test (DUT) that receives the test operation signals to output test result signals in response to test pattern signals of the test operation signals; and
a test interface board configured to transfer the test operation signals to the DUT, wherein the test interface board comprises:
at least one switch matrix including a plurality of switching elements that connect a plurality of connection nodes to each other, the at least one switch matrix configured to connect a plurality of channels of the ATE to respective pin positions corresponding to the DUT in response to switching control signals, the plurality of channels providing test operation signals for testing the DUT; and
a control logic configured to generate the switching control signals based on pin configuration information of the DUT.

15. The test system of claim 14, wherein the plurality of switching elements comprises:
a plurality of row switching elements configured to selectively connect two adjacent connection nodes of the plurality of connection nodes arranged to extend in a first direction in response to the switching control signals; and
a plurality of column switching elements configured to selectively connect two adjacent connection nodes of the plurality of connection nodes arranged to extend in a second direction that is transverse the first direction in response to the switching control signals.

16. The test system of claim 14,
wherein the at least one switch matrix comprises first and second switch matrices which are positioned on respective first and second layers,
wherein the test interface board further comprises a plurality of interlayer switching elements configured to selectively connect first connection nodes in the first switch matrix on the first layer to corresponding second connection nodes in the second switch matrix on the second layer, and
wherein the plurality of interlayer switching elements are configured to provide non-overlapping test signal paths when connections between the plurality of channels and the corresponding pin positions overlap in a same switch matrix.

17. A test interface board, comprising:
a plurality of nodes arranged in a matrix having a first direction of extension and a second direction of extension, the first and second directions being transverse each other;
a plurality of first switching elements configured to selectively connect adjacent nodes arranged in the first direction in response to switching control signals;
a plurality of second switching elements configured to selectively connect adjacent nodes arranged in the second direction in response to the switching control signals; and
a plurality of first positions corresponding to channels of an automated test equipment (ATE) and a plurality of second positions corresponding to pin positions of a device under test (DUT), wherein, in response to the switching control signals, the test interface board is programmed to provide multiple test signal paths, a signal path being between a selected one of the plurality of first positions and a selected one of the plurality of second positions, and the signal path further including a selected plurality of the nodes selectively connected by the first and second switching elements.

18. The test interface board of claim 17, wherein the nodes and first and second switching elements are arranged on first and second layers, each of the first and second layers comprising a plurality of nodes, a plurality of first switching elements and a plurality of second switching elements, and further comprising a plurality of third switching elements configured to selectively connect adjacent nodes of the first and second layers.

19. The test interface board of claim 18, wherein the signal path further includes selected nodes of the first and second layers selectively connected by the third switching elements.

20. The test interface board of claim 18, wherein two signal paths that otherwise would intersect on one of the first and second layers, are configured to overlap through the third switching elements and nodes of the other of the first and second layers.
